(19) United States
(12) Patent Application Publication
(10) Pub. No.: US 2025/0194189 A1
(43) Pub. Date: Jun. 12, 2025

(54) Devices with compositionally graded alloy layers

(71) Applicant: Cornell University, Ithaca, NY (US)

(72) Inventors: Shivali Agrawal, Ithaca, NY (US); Len van Deurzen, Ithaca, NY (US); Joseph Dill, Ithaca, NY (US); Jimy Encomendero, Ithaca, NY (US); Huili (Grace) Xing, Ithaca, NY (US); Debdeep Jena, Ithaca, NY (US)

(73) Assignee: Cornell University, Ithaca, NY (US)

(21) Appl. No.: 18/973,384

(22) Filed: Dec. 9, 2024

Related U.S. Application Data
(60) Provisional application No. 63/608,246, filed on Dec. 9, 2023.

(51) Int. Cl. H10D 62/824; C30B 29/40; H01L 21/02; H10D 8/60; H10D 30/83; H10D 30/87; H10D 62/85; H10D 62/852

(52) U.S. Cl. CPC H10D 62/824; H01L 21/0254; H10D 62/8503; H10D 62/852; C30B 29/403; C30B 29/406; H10D 8/60; H10D 30/83; H10D 30/87

(57) ABSTRACT

A semiconductor device that includes at least one not intentionally doped compositionally graded ternary, quaternary, quinary or senary ultra-wide bandgap alloy layer. Composition grading along a predetermined axis and changes in energy bandgap in space by compositional grading, alloy material, and effects of said any adjacent layers results in the at least one not intentionally doped compositionally graded ternary, quaternary, quinary or senary ultra-wide bandgap alloy layer being one of an n-type layer with a density distribution of electrons or a p-type layer with a density distribution of holes, depending on design choices. The at least one not intentionally doped compositionally graded ternary, quaternary, quinary or senary ultra-wide bandgap alloy layer is disposed on a substrate layer.

### CROSS-REFERENCE TO RELATED APPLICATIONS

This application claims priority to U.S. Provisional Patent Application No. 63/608,246, entitled DEVICES WITH COMPOSITIONALLY GRADED ALLOY LAYERS, filed Dec. 9, 2023, which is incorporated herein by reference in its entirety and for all purposes.

### STATEMENT REGARDING FEDERALLY SPONSORED RESEARCH OR DEVELOPMENT

This invention was made with U.S. Government support from the U.S. Department of Energy under grant No. DE-SC0021230 and National Science Foundation under grant No. NNCI-2025233. The U.S. Government has certain rights in the invention.

### BACKGROUND

This invention relates generally to devices with compositionally graded alloy layers and, more specifically. to distributed polarization doped alloy layers.

Aluminum gallium nitride (AlGaN) based p-n junction diodes are promising devices for advancing high power electronics and deep ultraviolet (UV) photonics. These applications are enabled by the following desirable properties of the AlGaN semiconductor system: a large tunable direct energy bandgap (3.4-6.2 eV), high critical electric field (3-15 MV/cm), and high thermal conductivity (260 W/mK for GaN and 340 W/mK for AlN), amongst others. p-type doping is the major bottleneck in realizing a p-n junction using these ultrawide bandgap semiconductors. The acceptor ionization energy (Eₐ) of magnesium (Mg) increases with the energy bandgap from GaN (˜200 meV) to AlN (˜630 meV³). Recent reports on p-type doping of AlN with lower acceptor binding energies and new shallow dopants like Be are under further investigation.

Deep acceptors with Eₐ>>k_{B}T (thermal energy) lead to poor ionization, low free carrier concentrations, and increased on-resistance in the diode p-type region. The large disparity between electron and hole carrier concentration and mobility causes an efficiency drop in light emitting diodes (LEDs). Several allied limitations with using a high concentration of Mg in active regions include surface polarity inversion, Mg precipitation, surface segregation, self-compensating defects formation, memory effects, and increased frequency dispersion in diodes, among others. In the design of waveguides for deep-UV laser diodes, Mg-doped cladding layers are undesirable because they cause high Mg-induced optical losses that increase the threshold gain. Similar p-type doping problems exist for all the Group III-nitrides.

Wide-bandgap semiconductors (also known as WBG semiconductors or WBGSs) are semiconductor materials that have a larger band gap than conventional semiconductors. Conventional semiconductors like silicon have a bandgap in the range of 0.6-1.5 electron Volt (eV), whereas wide-bandgap materials have bandgaps in the range above 3 eV (see Saravanan Yuvaraja, Vishal Khandelwal, Xiao Tang, Xiaohang Li, Chip, Available online 14 Oct. 2023, https://doi.org/10.1016/j.chip.2023.100072, which is incorporated by reference herein in its entirety and for all purposes). Generally, wide-bandgap semiconductors have electronic properties which fall in between those of conventional semiconductors and insulators. Some of the III-nitrides are ultra-wide-bandgap semiconductors (have a bandgap >1.5 times the threshold)

Wide-bandgap semiconductors permit devices to operate at much higher voltages, frequencies, and temperatures than conventional semiconductor materials like silicon and gallium arsenide. Wide bandgap semiconductors are the key component used to make short-wavelength (green and blue) LEDs or lasers, and are also used in certain radio frequency applications, notably military radars. Ultra-wide bandgap semiconductors are key components for shorter wavelength UV LEDs and lasers and can expand applications in high voltage and high frequency electronics.

There is a need for ways to p-dope III-nitride semiconductors.

There is a further need for a way to p-dope ultra-wide-bandgap semiconductors.

### BRIEF SUMMARY

Ways to p-dope III-nitride semiconductors and p-doped ultra-wide-bandgap semiconductors are presented below.

There has been success in a polarization-induced (Pi) doping scheme, which gives rise to a high-mobility two-dimensional electron gas (2DEG) without the need for impurity dopants (see Oliver Ambacher et al., Two dimensional electron gases induced by spontaneous and piezoelectric polarization undoped and doped AlGaN/GaN heterostructures, JOURNAL OF APPLIED PHYSICS, VOLUME 87, NUMBER 1, 1 Jan. 2000, which is incorporated by reference herein in its entirety and for all purposes). Recently, a two-dimensional hole gas (2DHG) was also reported in undoped GaN/AlN structures (see U.S. Pat. No. 11,158,709, which is incorporated by reference herein in its entirety and for all purposes).

In wurtzite III/V nitride semiconductors, one way to overcome these challenges is to leverage the spontaneous and piezoelectric polarization of wurtzite III/V nitride semiconductors. Spatial compositional grading of AlGaN along the polar axis creates a fixed bulk 3D polarization bound charge, whose electric field enables the formation of mobile 3-dimensional charges of opposite polarity. Growth can be performed along the metal polar axis or along the nitrogen polar axis.

Growth along the metal polar axis includes:
grading from GaN to AlN (increasing Al fraction and decreasing Ga fraction) induces free electrons.
grading from AlN to GaN (decreasing Al fraction and increasing Ga fraction) induces free holes. The illustrative instantiation provided herein below uses the last approach to induce free holes.

Growth along the nitrogen polar axis includes:
grading from GaN to AlN (increasing Al fraction and decreasing Ga fraction) induces free holes.
grading from AlN to GaN (decreasing Al fraction and increasing Ga fraction) induces free electrons.

In one or more instantiations, the semiconductor device of these teachings includes at least one not intentionally doped compositionally graded ternary, quaternary, quinary or senary ultra-wide bandgap alloy layer. At least one of any adjacent layers is an ultra-wide bandgap alloy layer. Any of the adjacent layers can be a wide bandgap alloy layer. The composition grading along a predetermined axis and the changes in energy bandgap in space by compositional grading, alloy material, and effects of any adjacent layers results in the at least one not intentionally doped compositionally graded ternary, quaternary, quinary or senary ultra-wide bandgap alloy layer being a p-type layer with a density distribution of holes.

In one or more other instantiations, the semiconductor device of these teachings includes at least one not intentionally doped compositionally graded ternary, quaternary, quinary or senary ultra-wide bandgap alloy layer. Composition grading along a predetermined axis and changes in energy bandgap in space by compositional grading, alloy material, and effects of said any adjacent layers results in the at least one not intentionally doped compositionally graded ternary, quaternary, quinary or senary ultra-wide bandgap alloy layer being a n-type layer with a density distribution of electrons. The at least one not intentionally doped compositionally graded ternary, quaternary, quinary or senary ultra-wide bandgap alloy layer is disposed on a substrate layer. In one instance, in the semiconductor device of the one or more other instantiations of these teachings, the at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer, and the substrate layer is an ohmic contact layer. Another contact layer is disposed on the one not intentionally doped compositionally graded ternary, quaternary, quinary or senary ultra-wide bandgap alloy layer. The semiconductor device is a Schottky rectifier with the advantage of ultra-wide bandgap semiconductors.

In another instance, in the semiconductor device of the one or more other instantiations of these teachings, the at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer, and the one not intentionally doped compositionally graded ternary, quaternary, quinary or senary ultra-wide bandgap alloy layer extends from a first distance away from one side of the substrate layer to a second distance away from another side of the substrate layer. A first layer of higher density n-doped (n+) ultra-wide bandgap alloy is disposed on the substrate layer from one side of the one not intentionally doped compositionally graded ternary, quaternary, quinary or senary ultra-wide bandgap alloy layer to the one side of the substrate layer and extends from the substrate layer to a top surface of the one not intentionally doped compositionally graded ternary, quaternary, quinary or senary ultra-wide bandgap alloy layer. A second layer of higher density n-doped (n+) ultra-wide bandgap alloy is disposed on the substrate layer from another side of the one not intentionally doped compositionally graded ternary, quaternary, quinary or senary ultra-wide bandgap alloy layer to the other side of the substrate layer and extends from the substrate layer to a top surface of the one not intentionally doped compositionally graded ternary, quaternary, quinary or senary ultra-wide bandgap alloy layer. A source ohmic contact layer is disposed on the first layer of higher density n-doped (n+) ultra-wide bandgap alloy, a drain ohmic contact layer is disposed on the second layer of higher density n-doped (n+) ultra-wide bandgap alloy, and a gate ohmic contact layer is disposed on a center region of the one not intentionally doped compositionally graded ternary, quaternary, quinary or senary ultra-wide bandgap alloy layer. The semiconductor device is a MESFET with the advantage of ultra-wide bandgap semiconductors.

In another instantiation, the semiconductor device of the one or more other instantiations of these teachings also includes at least one other not intentionally doped compositionally graded ternary, quaternary, quinary or senary ultra-wide bandgap alloy layer; wherein composition grading along a predetermined axis and changes in energy bandgap in space by compositional grading, alloy material, and effects of any adjacent layers results in said at least one not intentionally doped compositionally graded ternary, quaternary, quinary or senary ultra-wide bandgap alloy layer being a p-type layer with a density distribution of holes. In that other instantiation, the at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer. The one not intentionally doped compositionally graded ternary, quaternary, quinary or senary ultra-wide bandgap alloy layer extends from the substrate layer to a first surface and having two channels, a first channel a distance away from a second channel, the two channels extending from the first surface to a second surface. The at least one other not intentionally doped compositionally graded ternary, quaternary, quinary or senary ultra-wide bandgap alloy layer is a second not intentionally doped compositionally graded ternary, quaternary, quinary or senary ultra-wide bandgap alloy layer. The second not intentionally doped compositionally graded ternary, quaternary, quinary or senary ultra-wide bandgap alloy layer extending from the first channel to the second channel and from the first surface to the second surface. A first source contact structure is disposed over the first channel, a second source contact structure is disposed over the second channel, and a gate contact structure is disposed over a center portion of the second not intentionally doped compositionally graded ternary, quaternary, quinary or senary ultra-wide bandgap alloy layer. The semiconductor device is a JFET with the advantage of ultra-wide bandgap semiconductors.

In yet another instance, the semiconductor device is a short wavelength light emitting diode with the advantage of ultra-wide bandgap semiconductors. In still another instance, the semiconductor device is a short wavelength Laser with the advantage of ultra-wide bandgap semiconductors.

Other instantiations are also within the scope of these teachings.

For a better understanding of the present teachings, together with other and further objects thereof, reference is made to the accompanying drawings and detailed description, and its scope will be pointed out in the appended claims.

### BRIEF DESCRIPTION OF THE DRAWINGS

FIG. 1A is a Cross-sectional view of the fabricated device structure in one instantiation of these teachings;

FIG. 1B is an SEM image of a 104 μm diameter device in one instantiation of these teachings;

FIG. 1C shows 2×2 μm² AFM micrographs of the top GaN surface of the as-grown sample indicating smooth surface and 2 dimensional growth mode in one instantiation of these teachings;

FIG. 1D shows Measured and simulated 2θ-ω XRD scans of the sample across the (002) diffractions in one instantiation of these teachings;

FIG. 1E shows RSMs across the asymmetric (−105) diffractions in one instantiation of these teachings;

FIG. 1F shows an instantiation of these teachings where the semiconductor device is a Schottky diode;

FIG. 1G shows an instantiation of these teachings where the semiconductor device is a MESFET;

FIG. 1H shows an instantiation of these teachings where the semiconductor device is a JFET;

FIG. 1I shows an instantiation of these teachings where the semiconductor device is a short wavelength light emitting diode;

FIG. 1J shows an instantiation of these teachings where the semiconductor device is a short wavelength Laser;

FIG. 1K shows an instantiation of these teachings where the semiconductor device is pn junction diode;

FIG. 2A shows Room temperature J-V characteristics of the diode in one instantiation of these teachings;

FIG. 2B shows the extracted ideality factor from (a) using equation (1) for one instantiation of these teachings;

FIG. 2C shows Temperature dependent J-V characteristics in reverse bias of the diode in one instantiation of these teachings;

FIG. 2D shows Temperature dependent J-V characteristics in forward bias of the diode in one instantiation of these teachings;

FIG. 3A shows Energy band diagram and free electron and hole concentration of the p-n diode at zero bias for the diode in one instantiation of these teachings;

FIG. 3B shows Room-temperature capacitance-voltage measurements at 30 kHz AC frequency for the diode in one instantiation of these teachings;

FIG. 3C shows the extracted charge-density profile in the graded AlGaN layer using equation (4) which matches well with the polarization charge calculations done using equations (2)-(3);

FIG. 4AI shows Room temperature electroluminescence collected from the backside of the device; FIG. 4AII shows the comparison (in logarithmic scale) between EL from the device and PL from an AlGaN sample with the same composition and doping as the n-layer of the device in one instantiation of these teachings; and

FIG. 4B represents an Energy band diagram of the diode at 5 V forward bias, along with the spatially resolved radiative recombination rate, with the downward arrow showing the radiative transition corresponding to the main emission peak.

### DETAILED DESCRIPTION

The following detailed description presents the currently contemplated modes of carrying out these teachings. The description is not to be taken in a limiting sense but is made merely for the purpose of illustrating the general principles of these teachings, since the scope of these teachings is best defined by the appended claims.

“Not intentionally doped AlN,” as used herein, refers to AlN deposited without intentionally introduced doping. Not intentionally doped AlN can have, in some instances, concentrations of Oxygen of about 4×10¹⁸ cm⁻³ and, in some instances, concentrations of Silicon slightly higher than 7×10¹⁷ cm⁻³ (see, for example, N. T. Son, M. Bickermann, and E. Janzén, Shallow donor and DX states of Si in AlN, APPLIED PHYSICS LETTERS 98, 092104 (2011), which is incorporated by reference herein in its entirety and for all purposes).

“Group III,” as used here in, refers to a group of elements in the periodic table including what are now called Group 13 elements: boron (B), aluminum (Al), gallium (Ga), indium (In), thallium (TI).

In a polarization-induced (Pi) doping scheme using graded composition (sometimes called distributed polarization doping), the total polarization charge P is the sum of the spontaneous polarization (Pₛₚ) and the piezoelectric polarization (P_{pz}), and taking x as the varying composition along the z direction, Pₛₚ and

P_{pz} can be written as

$$P ( x ) = {P}_{sp} ( x ) + {P}_{pz} ( x ) ,$$

and, from Poisson's equation,

$$ρ ( z ) = - ∇ \cdot P = - \frac{dP ( x )}{dx} \frac{dx}{dz}$$

Using the example of graded AlₓGa₁₋ₓN,
growth can be performed along the metal polar axis or along the nitrogen polar axis. Growth along the metal polar axis:
   grading from GaN to AlN (increasing Al fraction and decreasing Ga fraction) induces free electrons.
   grading from AlN to GaN (decreasing Al fraction and increasing Ga fraction) induces free holes. The illustrative instantiation provided herein below uses the last approach to induce free holes.

Growth along the nitrogen polar axis:
grading from GaN to AlN (increasing Al fraction and decreasing Ga fraction) induces free holes.
grading from AlN to GaN (decreasing Al fraction and increasing Ga fraction) induces free electrons. As can be seen from this, it is possible to obtain free electrons or free holes from distributed polarization doping.

The density of the free carriers is proportional to the gradient of the polarization of the semiconductor material. If the polarization changes linearly then the density will be constant, and if the polarization changes quadratically the density will change linearly and so on. The polarization is nearly proportional to the energy bandgap of the ultrawide bandgap semiconductor, so that way, the 3D carrier gas is formed by changing the energy bandgap in space by compositional grading of the atomic concentrations in the semiconductor.

In one or more instantiations, the semiconductor device of these teachings includes at least one not intentionally doped compositionally graded ternary, quaternary, quinary or senary ultra-wide bandgap alloy layer. At least one of any adjacent layers is an ultra-wide bandgap alloy layer. Any of the adjacent layers can be a wide bandgap alloy layer. The composition grading along a predetermined axis and the changes in energy bandgap in space by compositional grading, alloy material, and effects of any adjacent layers results in the at least one not intentionally doped compositionally graded ternary, quaternary, quinary or senary ultra-wide bandgap alloy layer being a p-type layer with a density distribution of holes.

In one instance, the at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer, and the one not intentionally doped compositionally graded ternary, quaternary, quinary or senary ultra-wide bandgap alloy layer is disposed on an n-doped ultra-wide bandgap alloy layer. In one instantiation, the n-doped ultra-wide bandgap alloy layer is disposed on an ultra-wide bandgap buffer layer. In some instantiations, a p-doped wide bandgap alloy layer is disposed on said one not intentionally doped compositionally graded ternary, quaternary, quinary or senary ultra-wide bandgap alloy layer.

In one illustrative instantiation, the one not intentionally doped compositionally graded ternary, quaternary, quinary or senary ultra-wide bandgap alloy layer includes at least two group III elements.

In another illustrative instantiation, the one not intentionally doped compositionally graded ternary, quaternary, quinary or senary ultra-wide bandgap alloy layer includes at least two group III elements and at least one element from elements boron, scandium, yttrium, or lanthanum.

In yet another illustrative instantiation, the one not intentionally doped compositionally graded ternary, quaternary, quinary or senary ultra-wide bandgap alloy layer includes AlₓGa₁₋ₓN, where x varies, the n-doped ultra-wide bandgap alloy layer includes Al_{y}Ga_{1-y}N; and the p-doped wide bandgap alloy layer includes p-doped GaN.

For all instantiations described herein, it is possible for the one not intentionally doped compositionally graded ternary, quaternary, quinary or senary ultra-wide bandgap alloy layer to include three or more of indium, gallium, aluminum, boron, scandium, yttrium, or lanthanum.

In one or more other instantiations, the semiconductor device of these teachings includes at least one not intentionally doped compositionally graded ternary, quaternary, quinary or senary ultra-wide bandgap alloy layer. Composition grading along a predetermined axis and changes in energy bandgap in space by compositional grading, alloy material, and effects of said any adjacent layers results in the at least one not intentionally doped compositionally graded ternary, quaternary, quinary or senary ultra-wide bandgap alloy layer being a n-type layer with a density distribution of electrons. The at least one not intentionally doped compositionally graded ternary, quaternary, quinary or senary ultra-wide bandgap alloy layer is disposed on a substrate layer.

In one instance, in the semiconductor device of the one or more other instantiations of these teachings, the at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer, and the substrate layer is an ohmic contact layer. Another contact layer is disposed on the one not intentionally doped compositionally graded ternary, quaternary, quinary or senary ultra-wide bandgap alloy layer. The semiconductor device is a Schottky rectifier with the advantage of ultra-wide bandgap semiconductors.

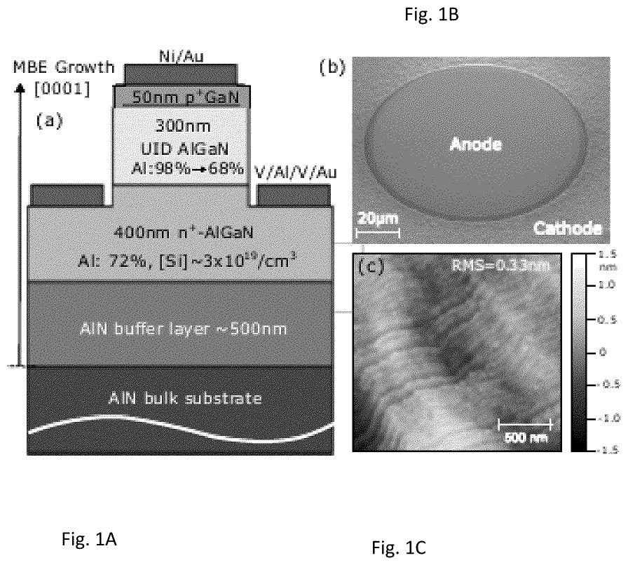

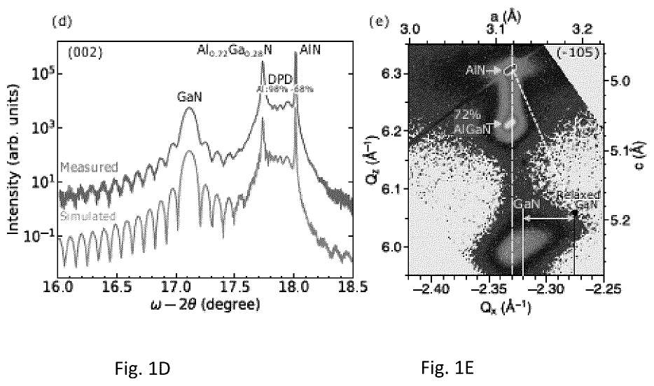

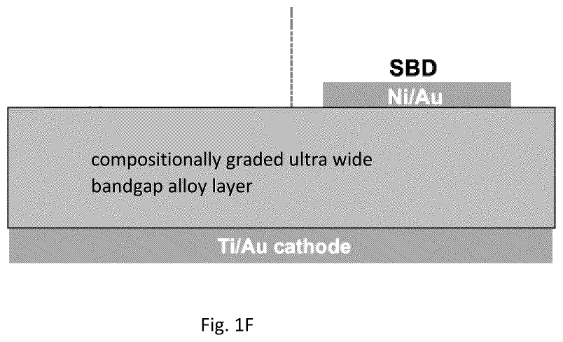

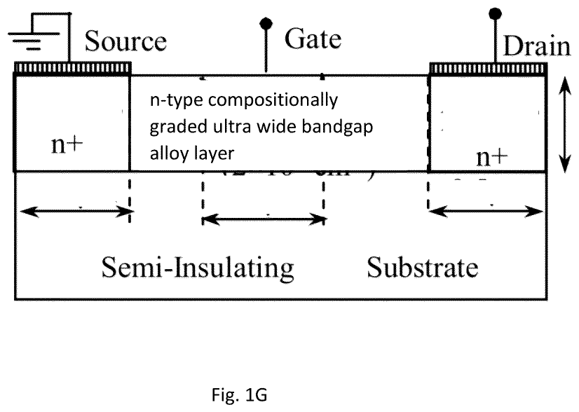

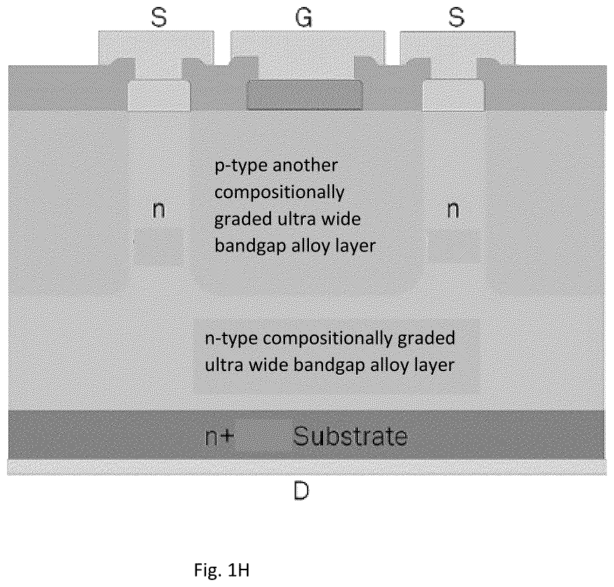

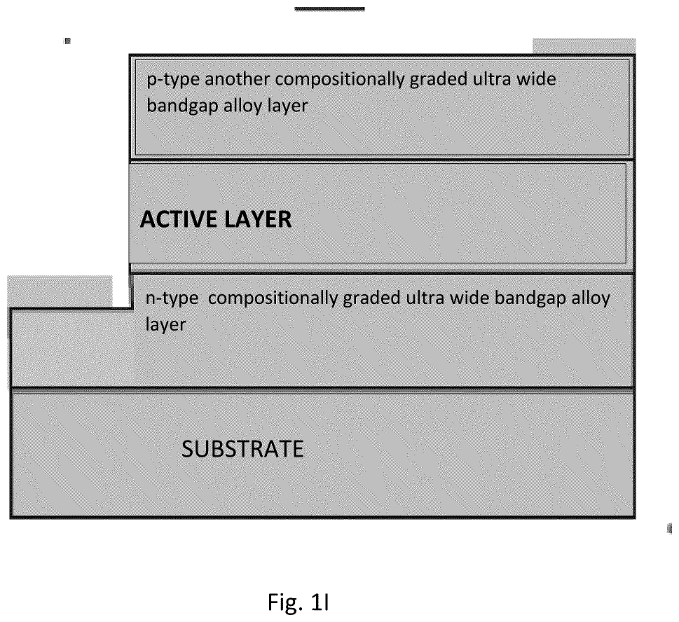

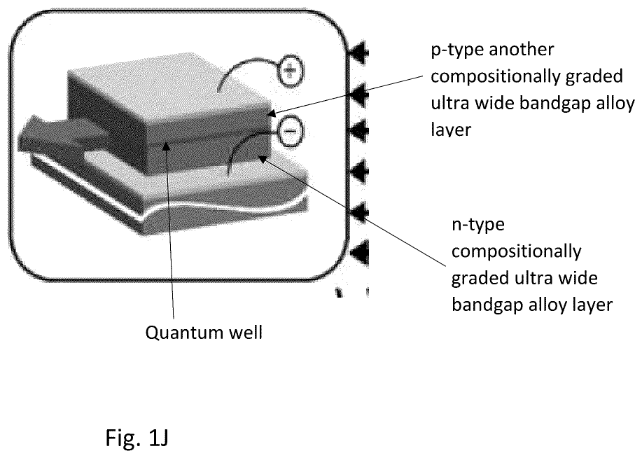

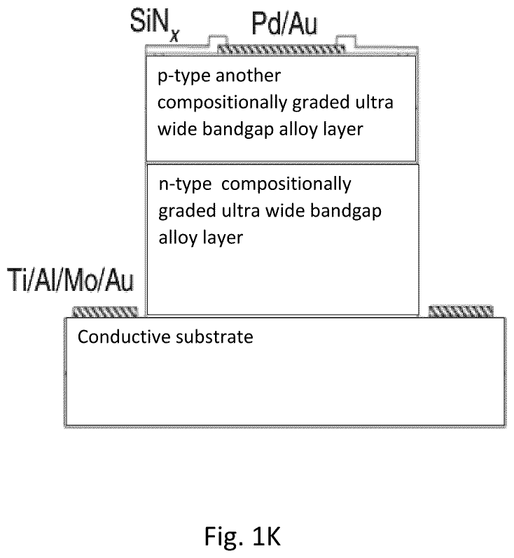

FIG. 1F shows an instantiation of these teachings where the semiconductor device is a Schottky diode. Referring to FIG. 1F, the compositionally graded ultra-wide bandgap alloy layer is disposed on an ohmic contact layer (a Ti/Au cathode layer in that instantiation) and another ohmic contact layer (a Ni/Au layer in that instantiation) is disposed on a portion of the compositionally graded ultra-wide bandgap alloy layer.

In another instance, in the semiconductor device of the one or more other instantiations of these teachings, the at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer, and the one not intentionally doped compositionally graded ternary, quaternary, quinary or senary ultra-wide bandgap alloy layer extends from a first distance away from one side of the substrate layer to a second distance away from another side of the substrate layer. A first layer of higher density n-doped (n+) ultra-wide bandgap alloy is disposed on the substrate layer from one side of the one not intentionally doped compositionally graded ternary, quaternary, quinary or senary ultra-wide bandgap alloy layer to the one side of the substrate layer and extends from the substrate layer to a top surface of the one not intentionally doped compositionally graded ternary, quaternary, quinary or senary ultra-wide bandgap alloy layer. A second layer of higher density n-doped (n+) ultra-wide bandgap alloy is disposed on the substrate layer from another side of the one not intentionally doped compositionally graded ternary, quaternary, quinary or senary ultra-wide bandgap alloy layer to the other side of the substrate layer and extends from the substrate layer to a top surface of the one not intentionally doped compositionally graded ternary, quaternary, quinary or senary ultra-wide bandgap alloy layer. A source ohmic contact layer is disposed on the first layer of higher density n-doped (n+) ultra-wide bandgap alloy, a drain ohmic contact layer is disposed on the second layer of higher density n-doped (n+) ultra-wide bandgap alloy, and a gate ohmic contact layer is disposed on a center region of the one not intentionally doped compositionally graded ternary, quaternary, quinary or senary ultra-wide bandgap alloy layer. The semiconductor device is a MESFET with the advantage of ultra-wide bandgap semiconductors.

FIG. 1G shows an instantiation of these teachings where the semiconductor device is a MESFET.

Referring to FIG. 1G, an n-type compositionally graded ultra-wide bandgap alloy layer is disposed on a portion of a semi-insulating substrate. A first layer of higher density n-doped (n+) ultra-wide bandgap alloy is disposed on the substrate layer from one side of the semi insulting layer to one side of the n-type compositionally graded ultra-wide bandgap alloy layer. A second layer of higher density n-doped (n+) ultra-wide bandgap alloy is disposed on the substrate layer from another side of the n-type compositionally graded ultra-wide bandgap alloy layer to the other side of the substrate layer. Bothe the first and second layer of higher density n-doped (n+) ultra-wide bandgap alloy extend from a top surface of the one not intentionally doped compositionally graded ternary, quaternary, quinary or senary ultra-wide bandgap alloy layer. A source contact is disposed on the first layer of higher density n-doped (n+) ultra-wide bandgap alloy, a drain contact layer is disposed on the second layer of higher density n-doped (n+) ultra-wide bandgap alloy, and a gate contact layer is disposed on a center region of the n-type compositionally graded ultra-wide bandgap alloy layer.

In another instantiation, the semiconductor device of the one or more other instantiations of these teachings also includes at least one other not intentionally doped compositionally graded ternary, quaternary, quinary or senary ultra-wide bandgap alloy layer; wherein composition grading along a predetermined axis and changes in energy bandgap in space by compositional grading, alloy material, and effects of any adjacent layers results in said at least one not intentionally doped compositionally graded ternary, quaternary, quinary or senary ultra-wide bandgap alloy layer being a p-type layer with a density distribution of holes.

In that other instantiation, the at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer. The one not intentionally doped compositionally graded ternary, quaternary, quinary or senary ultra-wide bandgap alloy layer extends from the substrate layer to a first surface and having two channels, a first channel a distance away from a second channel, the two channels extending from the first surface to a second surface. The at least one other not intentionally doped compositionally graded ternary, quaternary, quinary or senary ultra-wide bandgap alloy layer is a second not intentionally doped compositionally graded ternary, quaternary, quinary or senary ultra-wide bandgap alloy layer. The second not intentionally doped compositionally graded ternary, quaternary, quinary or senary ultra-wide bandgap alloy layer extends from the first channel to the second channel and from the first surface to the second surface. A first source contact structure is disposed over the first channel, a second source contact structure is disposed over the second channel, and a gate contact structure is disposed over a center portion of the second not intentionally doped compositionally graded ternary, quaternary, quinary or senary ultra-wide bandgap alloy layer. The semiconductor device is a JFET with the advantage of ultra-wide bandgap semiconductors.

FIG. 1H shows an instantiation of these teachings where the semiconductor device is a JFET. Referring to FIG. 1H, an n-type compositionally graded ultra-wide bandgap alloy layer is disposed on a substrate layer and extends to a first surface, a first and second channel extend from the first surface to a second surface. A p-type other compositionally graded ultra-wide bandgap alloy layer extends from the first channel to the second channel and from the first surface to the second surface. A first source contact structure is disposed over the first channel, a second source contact structure is disposed over the second channel, and a gate contact structure is disposed over a center portion of the p-type another compositionally graded ultra-wide bandgap alloy layer.

In yet another instance, the semiconductor device is a short wavelength light emitting diode with the advantage of ultra-wide bandgap semiconductors.

FIG. 1I shows an instantiation of these teachings where the semiconductor device is a short wavelength light emitting diode. (FIG. 1I was adapted from Yoshitaka Taniyasu† and Makoto Kasu, Improved Emission Efficiency of 210-nm Deep-ultraviolet Aluminum Nitride Light-emitting Diode, NTT Technical Review, available at https://www.ntt-review.jp/archive/ntttechnical.php?contents=ntr201008sf2.html). Referring to FIG. 1i, an n-type compositionally graded ultra-wide bandgap alloy layer is disposed on a substrate. An active layer is disposed on the n-type compositionally graded ultra-wide bandgap alloy layer. A p-type other compositionally graded ultra-wide bandgap alloy layer is disposed on the Active layer.

In still another instance, the semiconductor device is a short wavelength Laser with the advantage of ultra-wide bandgap semiconductors.

FIG. 1J shows an instantiation of these teachings where the semiconductor device is a short wavelength Laser. (FIG. 1J is adapted from Syed M. N. Hasan, Weicheng You, Md Saiful Islam Sumon and Shamsul Arafin, Recent Progress of Electrically Pumped AlGaN Diode Lasers in the UV-B and -C Bands, Photonics 2021, 8, 267. https://doi.org/10.3390/photonics8070267.) Referring to FIG. 1J, a p-type another compositionally graded ultra-wide bandgap alloy layer is disposed on a conductive layer, a quantum well structure is disposed on the p-type another compositionally graded ultra-wide bandgap alloy layer, a p-type another compositionally graded ultra-wide bandgap alloy layer is disposed on the quantum well structure, and another conductive layer is disposed on the p-type another compositionally graded ultra-wide bandgap alloy layer.

FIG. 1K shows an instantiation of these teachings where the semiconductor device is pn junction diode.

Referring to FIG. 1K, an n-type compositionally graded ultra-wide bandgap alloy layer is disposed on a conductive substrate. A p-type other compositionally graded ultra-wide bandgap alloy layer is disposed on the n-type compositionally graded ultra-wide bandgap alloy layer. Ah ohmic contact (Pd/Au in that instantiation) is disposed on a portion of the p-type other compositionally graded ultra-wide bandgap alloy layer. Also shown are ohmic contacts (Ti/Al/Mo/Au in that instantiation) on the conductive substrate, but other ways making contact to the conductive are possible.

Another illustrative instantiation is presented below to elucidate the present teachings. It should be noted that these teachings are not limited to limited to this instantiation.

In the teachings below, a DPD p-type layer was created by linearly grading down the AlGaN composition along the +c direction of the crystal. The grading creates a 3-dimensional hole gas. A one-sided n⁺-p heterojunction was used to measure the spatial density profile of the 3D hole gas. It was also found that the resulting ultrawide bandgap heterojunction diode current-voltage characteristics exhibit close to unity ideality factor, stable high temperature operation, and electroluminescence.

Space-charge profiling of DPD-based diodes grown on bulk AlN was recently reported in metal organic chemical vapor deposition (MOCVD) grown diodes (see Z. Zhang, M. Kushimoto, M. Horita, N. Sugiyama, L. J. Schowalter, C. Sasaoka, and H. Amano, “Space charge profile study of AlGaN-based p-type distributed polarization doped claddings without impurity doping for UV-C laser diodes,” Appl. Phys. Lett. 117, 152104 (2020)). There are no reports of such measurements on molecular beam epitaxial (MBE) grown devices. MBE offers some differences from MOCVD such as lower growth temperature, lower hydrogen incorporation, and the absence of memory effects enabling a precise dopant profiles and sharp heterointerfaces. While MBE grown 2D hole gases were demonstrated on single crystal AlN bulk substrates, polarization induced 3D hole gases on bulk AlN have not been realized yet. An MBE grown quasi-vertical p-n diode that uses an undoped distributed polarization doped layer for hole injection was presented. An average mobile hole concentration of 5.7×10¹⁷ cm⁻³ was found, consistent with what is expected from spontaneous and piezoelectric polarization effects. These findings make unintentionally doped DPD based diodes an attractive alternative to the conventional impurity based pn diodes.

The diode heterostructures were grown in a nitrogen plasma-assisted Veeco Gen10 molecular beam epitaxy (MBE) system on +c-plane single crystal bulk AlN substrates. The substrates were subjected to two essential cleaning steps as described in detail elsewhere: (1) an ex-situ cleaning using solvents and acids, and (2) an in-situ cleaning achieved through repeated cycles of Al adsorption and desorption, referred to as Al-assisted polishing. These steps eliminate the native surface oxides to enable high-quality homoepitaxy.

As shown in FIG. 1A, a 500 nm thick AlN buffer layer was grown at a high temperature of Tsub˜1060° C. in Al-rich conditions to isolate the device layers from remaining substrate surface impurities. The subsequent AlGaN epilayer was grown under Ga-rich conditions at a lower substrate temperature of 880° C. to enhance Ga incorporation. Excess metal was thermally desorbed at the end of each layer to ensure sharp heterojunctions. From bottom to top along the metal-polar growth direction, the targeted p-n diode heterostructure as seen in FIG. 1A consists of: (1) a 500 nm MBE grown AlN buffer layer, (2) a 400 nm Al_{0.7}Ga_{0.3}N layer with Si doping density N=1 3 ×10¹⁹ cm⁻³ which resulted in a free electron density n=12×10¹⁹ cm⁻³ at room temperature from Hall-effect measurements, (3) a not intentionally doped (UID) DPD layer linearly graded from Al0.95Ga0.05N to A_{10.65}Ga_{0.35}N over 300 nm, followed by (4) a 50 nm heavily Mg-doped GaN capping layer to form the metal p-contacts. In the entire device stack, the Mg impurity doping is only incorporated in the GaN p-contact layer and not in the Al containing UWBG layers.

Following epitaxy of the device heterostructures, the layers were fabricated into quasi-vertical diodes as indicated in FIG. 1A and shown in FIG. 1B. First, circular device mesas were formed by chlorine based inductively coupled plasma reactive ion etching (ICP-RIE) with a total etch depth extending 100 nm into the n-type AlGaN layer. The device mesa diameters range from 20 to 400 μm. Then, n-type metal-semiconductor contacts were formed by electron beam evaporation of a V/Al/V/Au stack of 20/80/40/100 nm thickness, which was subsequently rapid thermal annealed (RTA) at 800° C. for 60 seconds in a N2 ambience. Finally, p-type metal-semiconductor Ni/Au contacts of 15/20 nm thickness were deposited by electron beam evaporation and annealed by RTA at 450° C. for 30 seconds in an O2 environment. A 20/100 nm Ti/Au metal stack was subsequently deposited by electron beam evaporation for probing. Electrical measurements were performed using a Keithley 4200A semiconductor parameter analyzer. Electroluminescence spectra were collected using a Princeton Instruments spectrometer with 2400 grooves/mm and a blaze wavelength of 240 nm. All measurements were performed on devices with a 104 μm diameter, unless specified otherwise. FIG. 1A shows a cross-sectional view of the device, and FIG. 1B shows a scanning electron microscope (SEM) image of the fabricated device at a 45° tilt. The SEM was taken by a Zeiss ULTRA microscope at 5 kV beam voltage with an in-lens detector.

FIG. 1C shows atomic steps on the top p-GaN layer of the as-grown sample with a root mean square roughness of 0.33 nm over 2×2 μm² scan area measured by atomic force microscopy (AFM), confirming step flow growth mode throughout the structure. The X-ray diffraction (XRD) scans in FIG. 1D, performed using a Panalytical Empyrean system, show good agreement between the measured and simulated 20-w XRD scans of the sample across the (002) diffractions. The actual Al compositions found from XRD are 2-3% higher than the targeted structure. The reciprocal space map (RSM) around the asymmetric (1 05) diffractions in FIG. 1E shows that the AlGaN layers are fully strained to the AlN, while the GaN layer is relaxed and has an in-plane lattice strain of approximately 1.9%.

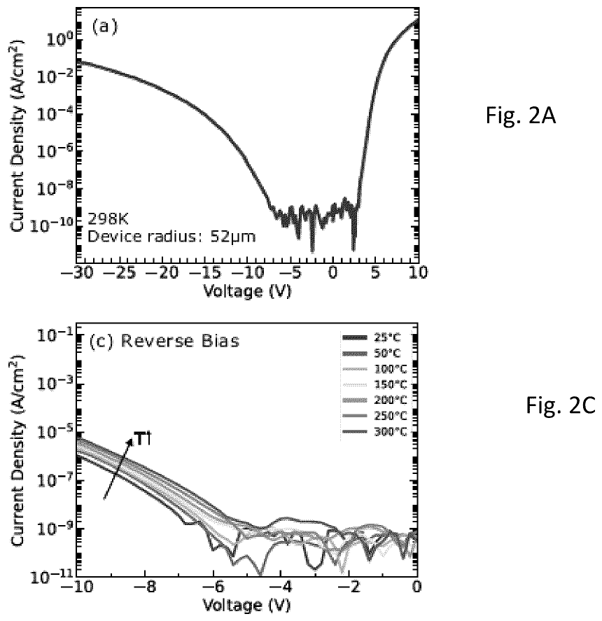

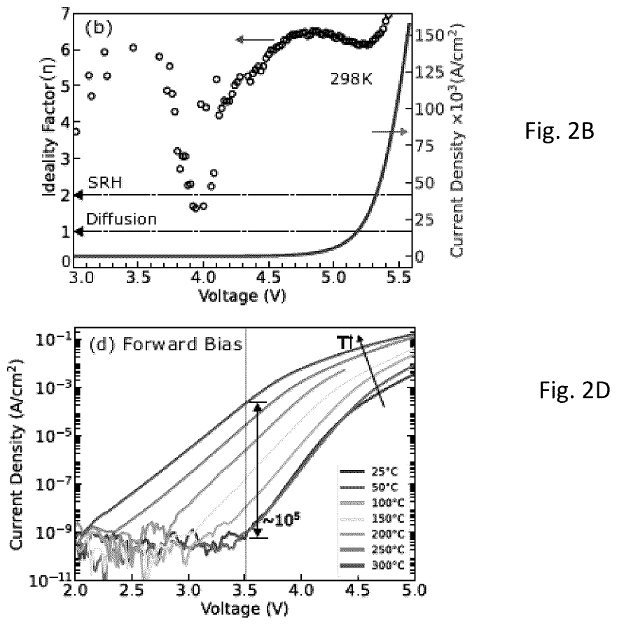

FIG. 2A shows the room temperature current-voltage characteristics of the diode. The reverse bias leakage current detection is limited by the 100 fA noise floor of the equipment until approximately −8 V, beyond which it increases gradually. In the forward bias, the diode turn-on voltage is approximately 5.5 V, and a specific on-resistance of 0.9 Ω·cm² at 6 V. The maximum measured forward current density of 1.3 kA/cm² at ˜ 20 V was limited by the current limit of the equipment. The measured 12 orders of current modulation (limited by the measurement noise floor and compliance) illustrate the capability of the AlGaN heterojunction p-n diode without Mg doping in the AlGaN layers.

FIG. 2B shows the turn-on behavior in linear scale, and the corresponding ideality factor. The diode forward current is

$${J}_{F} \approx {J}_{0} exp [ qV / ( η {k}_{b} T ) ] ,$$

where J₀ is a voltage-independent and material-dependent coefficient, q is the electron charge, V is the junction voltage, and n is the ideality factor. η=2 when non-radiative Shockley-Read-Hall interband recombination current is dominant, and η=1 when minority carrier diffusion current dominates. The voltage dependent ideality factor from the general diode relation

$$η = \frac{q}{{k}_{b} T} \times \frac{dV}{d ln ( J / {J}_{0} )} \qquad ( 1 )$$

is used to obtain the shown in FIG. 2B. n reaches a minimum value of approximately 1.63 in a narrow voltage range around 4 V near turn on, one of the lowest reported to date in ultrawide bandgap pn diodes. The deviation from the experimental ideality factor from the theoretical models (1≤η≤2) in AlGaN/GaN p-n junction diodes has been attributed to non-ohmic metal-semiconductor junctions. By performing transfer length method (TLM) measurements, it was found that both the p and n contacts are not entirely ohmic and exhibit some non-linearity. In this case the total ideality factor is the sum of individual ideality factors of all the rectifying junctions in the system as derived by Shah et al. (see M. Shah, Y.-L. Li, Th. Gessmann, and E. F. Schubert, “Experimental analysis and theoretical model for anomalously high ideality factors (n>>2.0) in AlGaN/GaNp-n junction diodes,” J. Appl. Phys. 94, 2627-2630 (2003)). The presence of the Schottky-like contact diodes in series with the pn junction diode therefore complicates an accurate determination of the true ideality factor of the pn junction itself.

FIGS. 2C and 2D show the temperature-dependence of the diode current from 25° C. to 300° C. The reverse leakage current in FIG. 2C increases with increasing electric field and temperature. This is a signature of trap-assisted tunneling being the dominant leakage mechanisms, such as the Frenkel-Poole (FP) process or variable-range hopping (VRH). A far more dramatic temperature dependence is seen in the forward bias current in FIG. 2D. For example, at 3.5 V forward bias the current density increases by 5 orders of magnitude when the temperature is increased from 25° C. to 300° C. A large exponential increase in current is indeed expected with temperature, because the intrinsic interband thermally generated carrier density is

$${n}_{i} ∝ exp ( - {E}_{g} / ( 2 {k}_{b} T ) ) ,$$

and in the ideal diode theory

$${J}_{0} ∝ {n}_{i}^{2} ∝ exp ( - {E}_{g} / ( {k}_{b} T ) )$$

is a strong function of temperature.

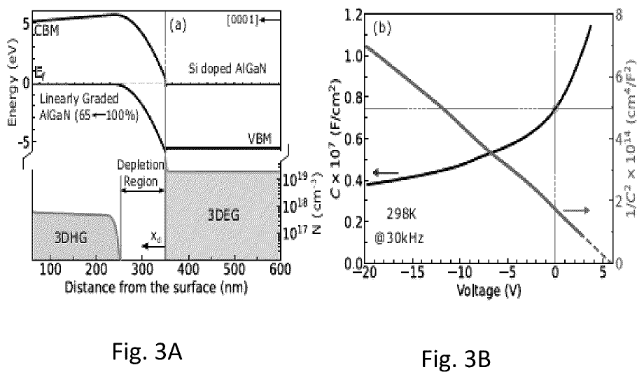

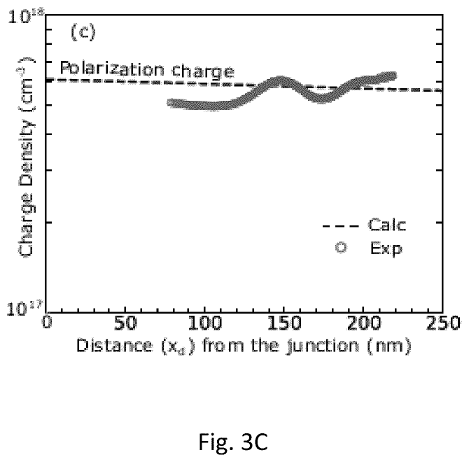

FIG. 3A shows the calculated energy band diagram of the pn heterojunction diode at zero bias, highlighting the depletion region. Unlike in non-polar pn diodes, at this polar AlN/AlGaN p-n heterojunction there is no depletion region in the n-side. Across the heterointerface of n-Al_{0.72}Ga_{0.28}N and AlN, there is a polarization discontinuity and an energy band discontinuity. Since the n-AlGaN is doped with donors, the combination gives rise to a 2-dimensional electron gas (2DEG) of density ˜1.64×10¹³ cm-2 at the heterojunction.

Because of this n-type accumulation region, the depletion region falls completely in the p-side. Furthermore, the mobile holes in the linearly graded AlGaN layer are due to distributed polarization doping. Thus, capacitance-voltage (CV) profiling should unambiguously extract the charge-density profile in the DPD layer. The low reverse bias leakage in this device (FIG. 2A) enables reliable CV measurements up to −20 V. The dc bias determines the depletion depth, and a 30 mV AC signal at a frequency of 30 kHz was used for the capacitance measurement in a standard parallel capacitance and conductance-model. FIG. 3B shows the measured capacitance as a function of the applied DC bias at room temperature. The loss tangent

$$tan δ = 2 π f ( {C}_{p} / {G}_{p} )$$

remains below 0.1 in the entire voltage range, ensuring the validity of the data. The built-in voltage of the junction from the extrapolation of 1/C2 vs V in FIG. 3[[(b)]]B is 5.8 V, close to the expected value of 5.5 V.

The 3D bulk polarization charge density in the DPD layer is the sum of both spontaneous and piezoelectric polarization

$${P}_{tot} = {P}_{PZ} + {P}_{SP} .$$

The piezoelectric polarization of AlₓGa₁₋ₓN coherently strained on AlN is,

$${P}_{PZ} ( x ) = 2 \times ( \frac{{a}_{{Al}_{x} {Ga}_{1 - x} N} - {a}_{AlN}}{{a}_{AlN}} ) \times ( {e}_{31} - {e}_{33} \frac{{c}_{13}}{{c}_{33}} ) , \qquad ( 2 )$$

where c₁₃ and c₃₃ are elastic coefficients and e₃₁ and e₃₃ are piezoelectric moduli. The values of spontaneous polarization, elastic coefficients and piezoelectric moduli for AlN and GaN were taken from Table 1 of Z. Zhang, M. Kushimoto, M. Horita, N. Sugiyama, L. J. Schowalter, C. Sasaoka, and H. Amano, “Space charge profile study of AlGaN-based p-type distributed polarization doped claddings without impurity doping for UV-C laser diodes,” Appl. Phys. Lett. 117, 152104 (2020). The corresponding values for _{AlxGal-xN} were obtained by linear interpolation (Vegard's law). The net carrier-density profile in cm⁻³ along the direction (z axis) is,

$$ρ ( z ) = \frac{1}{q} ∇ {( \cdot P )}_{tot} = \frac{1}{q} \frac{\partial P ( x ( z ) )}{\partial z} , \qquad ( 3 )$$

where x (z) is the graded Al-content profile along the z axis, a linear function in this case. The charge-density at the edge of the depletion region is extracted from the measured CV data of a one-sided abrupt junction,

$$N = \frac{- 2}{q {ϵ}_{s} {ϵ}_{0}} \times [ \frac{1}{d ( 1 / {C}^{2} ) / dV} ] , \qquad ( 4 )$$

where q is the electron charge, εₛ is the relative permittivity of the semiconductor at the edge of the depletion region, and 0 is the permittivity of vacuum. A constant value of 9.35 was used for εₛ corresponding to an average Al composition of 83% in the DPD layer, interpolated between AlN (εₛ=9.21) and GaN (εₛ=10.04). The depletion width in the DPD layer is

$${W}_{D} = ( {ϵ}_{0} {ϵ}_{s} ) / C .$$

FIG. 3B shows the experimentally measured, and the calculated charge-density profile (dashed line) along the direction. The experimental average charge density of 5.7 ×10¹⁷ cm⁻³ is approximately equal to the calculated density of 5.8×10¹⁷ cm⁻³. Thus, the presence of a high density polarization induced 3D hole gas close to the theoretically predicted density is observed. The rather interesting oscillations of the charge density observed in all devices are not captured in the simulation. They could originate either due to periodic fluctuations in Al composition, or due Friedel oscillations of the three-dimensional hole gas.

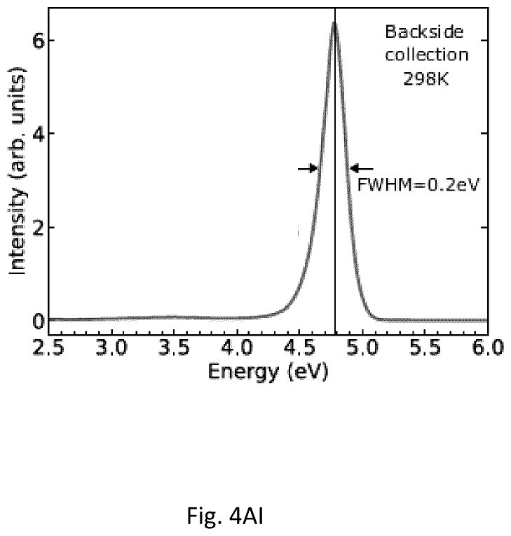

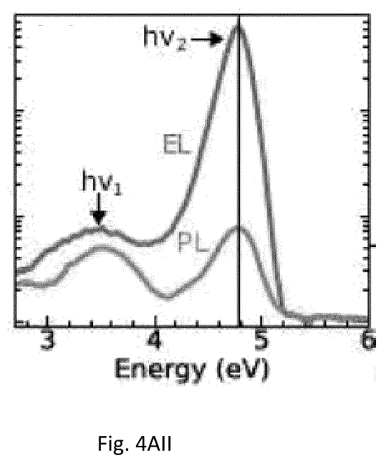

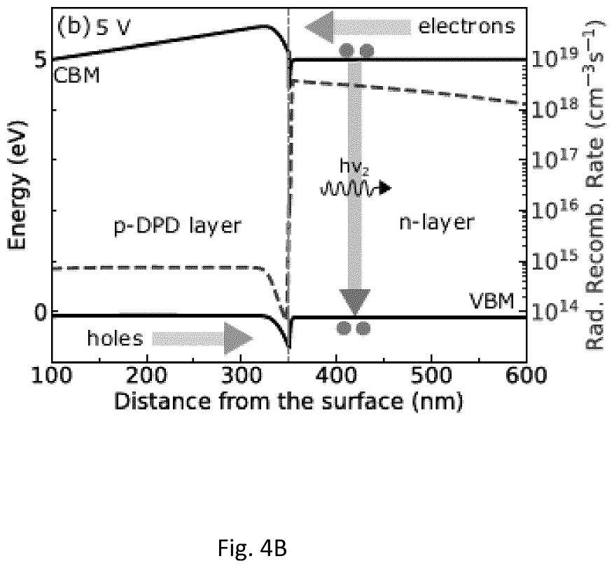

FIG. 4AI shows the measured room temperature electroluminescence (EL) collected from the backside of large 400 μm diameter devices at a forward current density of 110 A/cm² at room temperature. A peak at 4.78 eV dominates the emission spectrum. Additionally, a far less intense deep-level luminescence peak of energy ˜3.4 eV is also observed. To identify the origins of these peaks, room temperature photoluminescence (PL) experiments were also conducted on an Al_{0.72}Ga_{0.28}N/AlN sample with the same Si doping density and without the DPD and p-contact layers using a 193 nm ArF excimer laser excitation. FIG. 4AII shows a comparison of the EL and PL spectra. It confirms that the dominant emission peak in EL is from interband radiative recombination in the Si-doped A10.72Ga0.28N layer.

FIG. 4B shows the calculated energy-band diagram of the diode at a junction bias of 5 V, along with the spatially resolved radiative recombination rate, simulated using STR SiLENSe (software tool for 1D simulation of the active region of light-emitting diodes (LEDs) and laser diodes (LDs)). The purple arrow on the plot indicates the interband transition responsible for the dominant peak in the EL spectra, where the radiative recombination rate is nearly 10³ times more intense than in the p-DPD layer. The low to non-observable emission from the DPD layer in the EL spectrum is due to two reasons: (1) the product of electron higher in the n-layer leading to a higher radiative recombination rate since R∝np, and (2) the luminescence resulting from recombination within the DPD layer has higher energy than the energy bandgap of Al_{0.72}Ga_{0.28}N. This means photons emitted in the p-DPD layer moving towards the bulk will be absorbed and re-emitted at a photon energy equal to the n-layer energy bandgap during backside collection.

The weak sub-bandgap peak at approximately 3.4 eV is very close to the energy bandgap of GaN. This peak could be due to optical excitation of the top GaN layer from the emitted 4.8 eV photons which then make it across the wafer to the backside collector. But the appearance of a weak 3.4 eV peak in the inset of FIG. 4 (b) in the PL spectra of Al_{0.72}Ga_{0.28}N without any GaN layer indicates the EL peak is also from the n-AlGaN layer. Chichibu et al. have proposed the existence of defect complexes consisting of cation vacancies and silicon (V_{III-n}Si_{III}) as an explanation for the deep PL emission bands. These complexes act as self-compensating acceptor-type defects in Si doped AlN and AlGaN. But it should be noted that literature reports on luminescence in AlN and AlGaN grown by MBE are scarce, and that defect formation may strongly depend on the method of deposition.

In summary, ultrawide bandgap semiconductor diodes exhibiting low reverse bias leakage and high on/off ratio are realized by MBE, thanks to the low dislocation-density of the epilayers grown on bulk AlN substrates. Completely one-sided p-n heterojunction diodes are realized exploiting polarization induced doping on the n-side to remove the depletion layer, and distributed polarization doping instead of Mg acceptor doping for the p-type depletion layer. Through capacitance-voltage measurements, the mobile hole concentration and their spatial distribution in the graded AlGaN layers was directly measured and is found to be consistent with what is expected from polarization effects. These polarization-induced ultrawide bandgap semiconductor diodes show stable performance up to 300° C. The electroluminescence from these diodes is dominated by interband radiative recombination, and deep level luminescence is greatly suppressed. This suggests the presence of low point defect densities in the MBE-grown Si-doped AlGaN layer. Overall, these teachings demonstrate the flexibility in the design of new kinds of p-n heterojunction diodes through polarization-induced doping to achieve properties that are not possible in standard diodes. Such heterostructure design that combine bandgap engineering intimately with polarization engineering opens opportunities for more efficient photonic and electronic devices with ultrawide bandgap polar semiconductors than what is possible in nonpolar semiconductors.

As used herein, the singular forms “a,” “an,” and “the” include the plural reference unless the context clearly dictates otherwise. Except where otherwise indicated, all numbers expressing quantities of ingredients, reaction conditions, and so forth used in the specification and claims are to be understood as being modified in all instances by the term “about.”

For the purpose of better describing and defining the present teachings, it is noted that terms of degree (e.g., “substantially,” “about,” and the like) may be used in the specification and/or in the claims. Such terms of degree are utilized herein to represent the inherent degree of uncertainty that may be attributed to any quantitative comparison, value, measurement, and/or other representation. The terms of degree may also be utilized herein to represent the degree by which a quantitative representation may vary (e.g., +10%) from a stated reference without resulting in a change in the basic function of the subject matter at issue.

All cited references are incorporated by reference in their entirety and for all purposes.

It will be appreciated by those of ordinary skill in the pertinent art that the functions of several elements may, in alternative embodiments, be carried out by fewer elements or a single element. Similarly, in some embodiments, any functional element may perform fewer, or different, operations than those described with respect to the illustrated embodiment. While the subject technology has been described with respect to preferred embodiments, those skilled in the art will readily appreciate that various changes and/or modifications can be made to the subject technology without departing from the spirit or scope of the subject technology.

Although the invention has been described with respect to various embodiments, it should be realized these teachings are also capable of a wide variety of further and other embodiments within the spirit and scope of the appended claims.

What is claimed is:

1. A semiconductor device comprising:
at least one not intentionally doped compositionally graded ternary, quaternary, quinary or senary ultra-wide bandgap alloy layer; wherein at least one of any adjacent layers is an ultra-wide bandgap alloy layer; any of said adjacent layers is a wide bandgap alloy layer;
wherein composition grading along a predetermined axis and changes in energy bandgap in space by compositional grading, alloy material, and effects of said any adjacent layers results in said at least one not intentionally doped compositionally graded ternary, quaternary, quinary or senary ultra-wide bandgap alloy layer being a p-type layer with a density distribution of holes;
wherein said at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer; and
said one not intentionally doped compositionally graded ternary, quaternary, quinary or senary ultra-wide bandgap alloy layer being disposed on an n-doped ultra-wide bandgap alloy layer.

2. The semiconductor device of claim 1, wherein said n-doped ultra-wide bandgap alloy layer is disposed on an ultra-wide bandgap buffer layer.

3. The semiconductor device of claim 2, wherein a p-doped wide bandgap alloy layer is disposed on said one not intentionally doped compositionally graded ternary, quaternary, quinary or senary ultra-wide bandgap alloy layer.

4. The semiconductor device of claim 3, wherein said one not intentionally doped compositionally graded ternary, quaternary, quinary or senary ultra-wide bandgap alloy layer is disposed on a center section of the n-doped ultra-wide bandgap alloy layer; wherein a first ohmic contact layer is disposed on a section of the n-doped ultra-wide bandgap alloy layer between one end and before said one not intentionally doped compositionally graded ternary, quaternary, quinary or senary ultra-wide bandgap alloy layer and a second ohmic contact layer is disposed on a section of the n-doped ultra-wide bandgap alloy layer between after said one not intentionally doped compositionally graded ternary, quaternary, quinary or senary ultra-wide bandgap alloy layer and another end of the n-doped ultra-wide bandgap alloy layer; and wherein a third ohmic contact layer is disposed on p-doped wide bandgap alloy layer.

5. The semiconductor device of claim 2, wherein said one not intentionally doped compositionally graded ternary, quaternary, quinary or senary ultra-wide bandgap alloy layer comprises at least two group III elements and wherein the ultra-wide bandgap buffer layer comprises at least two other group III elements.

6. The semiconductor device of claim 2, wherein said one not intentionally doped compositionally graded ternary, quaternary, quinary or senary ultra-wide bandgap alloy layer comprises at least two group III elements and wherein the ultra-wide bandgap buffer layer comprises at least two other group III elements.

7. The semiconductor device of claim 1, wherein said one not intentionally doped compositionally graded ternary, quaternary, quinary or senary ultra-wide bandgap alloy layer comprises at least two group III elements and at least one element from elements boron, scandium, yttrium, or lanthanum.

8. The semiconductor device of claim 2, wherein said one not intentionally doped compositionally graded ternary, quaternary, quinary or senary ultra-wide bandgap alloy layer comprises at least two group III elements and at least one element from elements boron, scandium, yttrium, or lanthanum.

9. The semiconductor device of claim 3, wherein said at least one not intentionally doped compositionally graded ternary, quaternary, quinary or senary ultra-wide bandgap alloy layer comprises three or more of indium, gallium, aluminum, boron, scandium, yttrium, or lanthanum.

10. The semiconductor device of claim 4, wherein said one not intentionally doped compositionally graded ternary, quaternary, quinary or senary ultra-wide bandgap alloy layer comprises three or more of indium, gallium, aluminum, boron, scandium, yttrium, or lanthanum.

11. The semiconductor device of claim 5, wherein said one not intentionally doped compositionally graded ternary, quaternary, quinary or senary ultra-wide bandgap alloy layer comprises three or more of indium, gallium, aluminum, boron, scandium, yttrium, or lanthanum.

12. The semiconductor device of claim 5, wherein said one not intentionally doped compositionally graded ternary, quaternary, quinary or senary ultra-wide bandgap alloy layer comprises AlₓGa₁₋ₓN, where x varies; wherein the n-doped ultra-wide bandgap alloy layer comprises Al_{y}Ga_{1-y}N; and wherein p-doped wide bandgap alloy layer comprises p-doped GaN.

13. A semiconductor device comprising:
at least one not intentionally doped compositionally graded ternary, quaternary, quinary or senary ultra-wide bandgap alloy layer; wherein composition grading along a predetermined axis and changes in energy bandgap in space by compositional grading, alloy material, and effects of any adjacent layers results in said at least one not intentionally doped compositionally graded ternary, quaternary, quinary or senary ultra-wide bandgap alloy layer being a n-type layer with a density distribution of electrons;
and wherein said at least one not intentionally doped compositionally graded ternary, quaternary, quinary or senary ultra-wide bandgap alloy layer is disposed on a substrate layer.

14. The semiconductor device of claim 13, wherein said wherein said at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer; wherein the substrate layer is an ohmic contact layer; wherein another contact layer is disposed on said one not intentionally doped compositionally graded ternary, quaternary, quinary or senary ultra-wide bandgap alloy layer; and wherein the semiconductor device is a Schottky rectifier.

15. The semiconductor device of claim 13, wherein said at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer; wherein said one not intentionally doped compositionally graded ternary, quaternary, quinary or senary ultra-wide bandgap alloy layer extends from a first distance away from one side of the substrate layer to a second distance away from another side of the substrate layer; wherein a first layer of higher density n-doped (n⁺) ultra-wide bandgap alloy is disposed on the substrate layer from one side of said one not intentionally doped compositionally graded ternary, quaternary, quinary or senary ultra-wide bandgap alloy layer to said one side of the substrate layer and extends from the substrate layer to a top surface of the said one not intentionally doped compositionally graded ternary, quaternary, quinary or senary ultra-wide bandgap alloy layer; and wherein a second layer of higher density n-doped (n⁺) ultra-wide bandgap alloy is disposed on the substrate layer from another side of said one not intentionally doped compositionally graded ternary, quaternary, quinary or senary ultra-wide bandgap alloy layer to said another side of the substrate layer and extends from the substrate layer to a top surface of said one not intentionally doped compositionally graded ternary, quaternary, quinary or senary ultra-wide bandgap alloy layer.

16. The semiconductor device of claim 15, wherein a source ohmic contact layer is disposed on the first layer of higher density n-doped (n⁺) ultra-wide bandgap alloy, a drain ohmic contact layer is disposed on the second layer of higher density n-doped (n⁺) ultra-wide bandgap alloy, and a gate ohmic contact layer is disposed on a center region of said one not intentionally doped compositionally graded ternary, quaternary, quinary or senary ultra-wide bandgap alloy layer; and wherein the semiconductor device is a MESFET.

17. The semiconductor device of claim 13 further comprising at least one other not intentionally doped compositionally graded ternary, quaternary, quinary or senary ultra-wide bandgap alloy layer; wherein composition grading along a predetermined axis and changes in energy bandgap in space by compositional grading, alloy material, and effects of said any adjacent layers results in said at least one not intentionally doped compositionally graded ternary, quaternary, quinary or senary ultra-wide bandgap alloy layer being a p-type layer with a density distribution of holes; wherein said at least one not intentionally doped compositionally graded ternary, quaternary, quinary or senary ultra-wide bandgap alloy layer is one not intentionally doped compositionally graded ternary, quaternary, quinary or senary ultra-wide bandgap alloy layer; wherein said one not intentionally doped compositionally graded ternary, quaternary, quinary or senary ultra-wide bandgap alloy layer extends from the substrate layer to a first surface and having two channels, a first channel a distance away from a second channel, the two channels extending from the first surface to a second surface; wherein said at least one other not intentionally doped compositionally graded ternary, quaternary, quinary or senary ultra-wide bandgap alloy layer is a second not intentionally doped compositionally graded ternary, quaternary, quinary or senary ultra-wide bandgap alloy layer; said second not intentionally doped compositionally graded ternary, quaternary, quinary or senary ultra-wide bandgap alloy layer extending from the first channel to the second channel and from the first surface to the second surface.

18. The semiconductor device of claim 17, wherein a first source contact structure is disposed over the first channel, a second source contact structure is disposed over the second channel, and a gate contact structure is disposed over a center portion of said second not intentionally doped compositionally graded ternary, quaternary, quinary or senary ultra-wide bandgap alloy layer; and wherein the semiconductor device is a JFET.

19. The semiconductor device of claim 13, wherein said at least one not intentionally doped compositionally graded ternary, quaternary, quinary or senary ultra-wide bandgap alloy layer comprises three or more of indium, gallium, aluminum, boron, scandium, yttrium, or lanthanum.

20. The semiconductor device of claim 14, wherein said at least one not intentionally doped compositionally graded ternary, quaternary, quinary or senary ultra-wide bandgap alloy layer comprises three or more of indium, gallium, aluminum, boron, scandium, yttrium, or lanthanum.
